(19) United States
(12) Patent Application Publication
(10) Pub. No.: US 2015/0038039 A1
(43) Pub. Date: Feb. 5, 2015

(54) ORGANIC-INORGANIC HYBRID MATERIAL FILM AND METHOD FOR MANUFACTURING THE SAME

(71) Applicant: ITEQ CORPORATION, Taoyuan County (TW)

(72) Inventors: Chao-Hui KUO, Taoyuan County (TW); Ming-Hung HUANG, Taoyuan County (TW); Po-Hsun LEE, Taoyuan County (TW); Shun-Cheng WANG, Taoyuan County (TW)

(73) Assignee: ITEQ CORPORATION, Taoyuan County (TW)

(21) Appl. No.: 13/956,884

(22) Filed: Aug. 1, 2013

(51) Int. Cl. C09D 151/00; H05K 1/03; B05D 3/02

(52) U.S. Cl. CPC C09D 151/003; B05D 3/0254; H05K 1/0366
USPC 442/180; 524/549; 427/387; 428/221

(57) ABSTRACT

The invention provides a method for manufacturing an organic-inorganic hybrid material film. The method mainly comprises hybridization of polymaleic anhydride-polyimide and silica by sol-gel route and by using a silane coupling agent to produce a structure of polymaleic anhydride-polyimide having silane, then casting and curing to form a material film. Also, the invention provides a polymaleic anhydride-polyimide-silica organic-inorganic hybrid material film.

### BACKGROUND OF THE INVENTION

1. Technical Field

The invention relates to a method for manufacturing an organic-inorganic hybrid material film, particularly to a method for manufacturing an organic-inorganic hybrid material film of polymaleic anhydride-polyimide-silica.

2. Related Art

Composites can be manufactured by combining a variety of materials such as polymers and inorganic compounds, and have properties of both polymers and inorganic compounds. For example, polymers are easy to process and inexpensive, and have excellent properties such as high toughness, elasticity, corrosion resistance, but have poor properties of heat resistance and mechanical strength. On the other hand, inorganic compounds such as ceramics are hard, and have low activity, excellent heat resistance and mechanical strength, but are fragile and have a heavier weight. A brand new material can be obtained by combining a variety of materials with their advantages. Conventional composites have been manufacturing by blending polymers such as polyethylene, polypropylene, polystyrene and polymethyl methacrylate, nylon, polyester and polyimide; and inorganic compounds such as calcium carbonate, clay and silica. However, organic-inorganic hybrid materials that are manufactured by chemical methods of sol-gel route or self-assembly in combination to polymer moieties and inorganic compound moieties may exhibit excellent properties that are preferable than conventional composites thereof.

Polyimides are suitable in combination to inorganic compounds to form organic-inorganic hybrid materials because polyimides have excellent heat resistance, mechanical properties and chemical resistance. Therefore, the organic-inorganic hybrid materials containing polyimides are widely used in the aerospace industry, electronic materials, etc. Now the polyimides that are generally in use are mostly aromatic polyimides. However, most of the aromatic polyimide cannot be dissolved in the solvent and is non-thermoplastic, and thus difficult to process. Polyamic acid that is precursor of polyimide can be dissolved in the solvent. Therefore, polyimide may be formed by forming a desired shape by the polyamic acid solution, and then imidization is carried out.

However, imidization is accompanied by water evaporation because the reaction temperature of thermal imidization has reached more than 300° C. that exceeds the boiling point of water. Accordingly, the disadvantage of wrinkled surface of the thick film formed of the polyimide resin by the thermal ring closure step will occur. The temperature for film forming is hard to select properly. On the other hand, the film formed of the polyamic acid fails to keep a property of excellent temperature resistance of the polyimide as the imidization is omitted. Also, polyamic acid solution is hard to preserve, because hydrolysis of the polyamic acid solution is easy to occur in presence of water.

Polyimides are used extensively in the electronic fields as insulation film or protective coating on semiconductor devices. Especially, aromatic polyimides play an important role for high density and multi-function of flexible printed circuit substrates and integrated circuits due to the excellent temperature resistance, mechanic strength and insulation property.

Accordingly, precursor solution of polyimides is typically used for the formation of interlayer insulation film or protective coating of micro-circuit. The precursor solution of polyimides such as polyamic acid (PAA) solution, polyamic acid acetate solution, polyamic acid trimethylsilyl acetate solution and polyamic acid bis(diethyl amide) solution may be formed by reacting diamine compounds with tetracarboxylic dianhydride. The precursor solutions of polyimides are all polymer solution with high degree of polymerization. Typically, the film of polyimides is formed by coating the polymer solution on a substrate such as copper or glass, and then heated to carry out imidization and remove the solvent.

However, it is required to reduce the concentration of solute for obtaining a proper viscosity of the polymer solution when coating the polymer solution with high degree of polymerization. On the other hand, in order to increase the production, it is required to increase the concentration of solute, and thus the polymer solution has an increased viscosity and is difficult for coating. Further, if polymers with low molecular weight are manufactured to obtain a proper viscosity of the polymer solution for coating, it is not able to form a film with excellent temperature resistance and mechanic strength. Moreover, the polymer solution is hard to preserve in a condition of maintaining the original degree of polymerization for a long time.

### SUMMARY OF THE INVENTION

An object of the invention is to provide, an organic-inorganic hybrid material film of polymaleic anhydride-polyimide-silica in which a polymaleic anhydride-polyimide phase contains polymaleic anhydride as a main chain, and the polymaleic anhydride grafting with reactively terminated functional groups for crosslinking at side chain positions, wherein the short chain has polyimide structure. The side chains are short that can decrease the degree of polymerization, and thus can avoid polymer solution too much viscous to form film by coating.

Another object of the invention is to provide a method for manufacturing an organic-inorganic hybrid material film of polymaleic anhydride-polyimide-silica in which a polymaleic anhydride-polyimide phase contains polymaleic anhydride as a main chain. Because the invention uses a chemical ring closure step, the disadvantage of wrinkled surface of the thick film formed of the polyimide resin by the thermal ring closure step can be avoided.

Further another object of the invention is to provide a prepreg which has excellent temperature resistance and mechanical strength, and can be an insulation layer material for use in copper foil substrates and circuit boards. Still another object of the invention is to provide a copper foil substrate which has excellent temperature resistance and mechanical strength, and bonds with electronic elements to form an electronic device that can be operated in a strict environment of high temperature and high humidity without deterioration.

To accomplish the above object, there is provided an organic-inorganic hybrid material film of polymaleic anhydride-polyimide-silica in which a polymaleic anhydride-polyimide phase contains polymaleic anhydride as a main chain, and the polymaleic anhydride grafting with reactively terminated functional groups for crosslinking at side chain positions, wherein the position of short chain has polyimide moiety and silica moiety combining each other.

The invention provides a method for manufacturing an organic-inorganic hybrid material film of polymaleic anhydride-polyimide-silica. The method comprises steps of: (i) dissolving and reacting a dianhydride with a diamine in a solvent to form polyamic acid; (ii) reacting polymaleic anhydride with the polyamic acid produced by the step (i) under a temperature below 80° C. to form the polymaleic anhydride grafting with —NH—CO— group and oligomer having carboxylic acid group at side chains; (iii) adding a silane coupling agent; (iv) carrying out a chemical ring-closure of the polyamic acid by adding a catalyst into a solution obtained from step (iii); (v) forming an organic-inorganic hybrid material solution of polymaleic anhydride-polyimide-silica by adding an alkoxysilane monomer having formula of Si(R3)4, where R3 may be the same or not the same and represents halogens, C1-6 alkoxy group, C2-6 enyloxy group and aryloxy group into a solution obtained from step (iv); and (vi) forming an organic-inorganic hybrid material film of polymaleic anhydride-polyimide-silica by coating and curing the organic-inorganic hybrid material solution of polymaleic anhydride-polyimide-silica on a substrate.

Also, the invention provides a prepreg formed of a fiberglass cloth impregnated in the above organic-inorganic hybrid material solution of polymaleic anhydride-polyimide-silica. Further, the invention provides a copper foil substrate including a copper foil laminated with the above prepreg.

### BRIEF DESCRIPTION OF THE DRAWINGS

FIG. 1 is a flow chart of a method for manufacturing an organic-inorganic hybrid material film of polymaleic anhydride-polyimide-silica of an embodiment of the present invention.

FIG. 2 is a diagram showing reactions for manufacturing an organic-inorganic hybrid material of polymaleic anhydride-polyimide-silica of an embodiment of the present invention, wherein a silane coupling agent for use in the reaction is an amine group coupling agent having formula of H2N—R1-Si(R2)3.

FIG. 3 is a diagram showing reactions for manufacturing an organic-inorganic hybrid material of polymaleic anhydride-polyimide-silica of another embodiment of the present invention, wherein a silane coupling agent for use in the reaction is an isocyanic acid group coupling agent having formula of OCN—R1-Si(R2)3.

FIG. 4 is a graph showing IR absorption spectroscopy of an organic-inorganic hybrid material of polymaleic anhydride-polyimide-silica of an embodiment of the invention.

FIG. 5 is an analytical result of FIG. 4.

FIG. 6 is a graph showing phase transition of an organic-inorganic hybrid material of polymaleic anhydride-polyimide-silica of the invention measured by differential scanning calorimetry (DSC).

FIG. 7 is a graph showing the weight residue of an organic-inorganic hybrid material of polymaleic anhydride-polyimide-silica of the invention when heated to various temperatures.

### DETAILED DESCRIPTION OF THE INVENTION

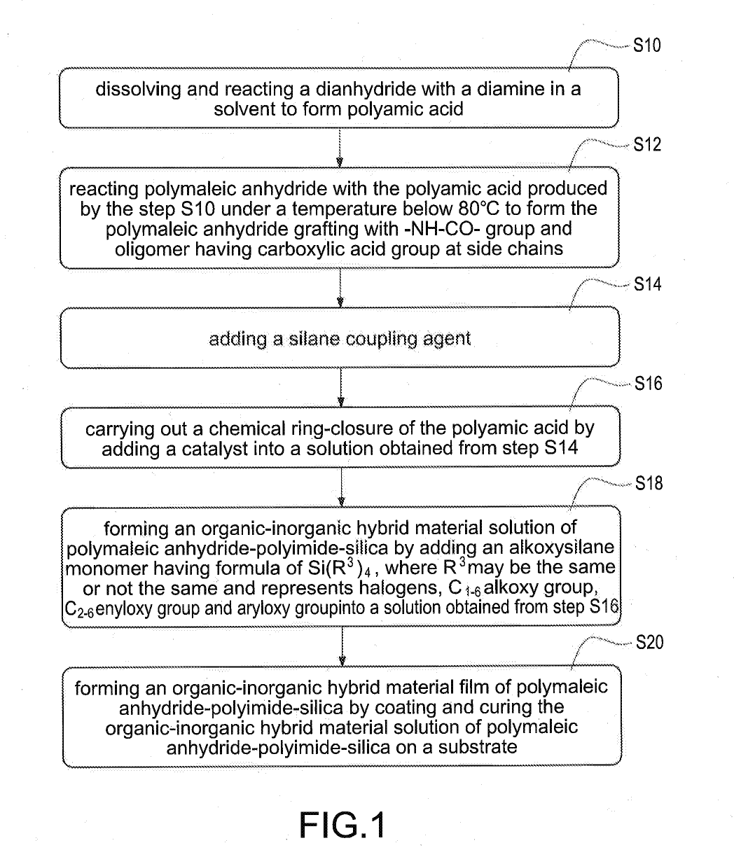

Please refer to FIG. 1. FIG. 1 is a flow chart of a method for manufacturing an organic-inorganic hybrid material film of polymaleic anhydride-polyimide-silica of an embodiment of the present invention. The method comprises steps of: dissolving and reacting a dianhydride with a diamine in a solvent to form polyamic acid, as shown in step S10; reacting polymaleic anhydride with the polyamic acid produced by the step S10 under a temperature below 80° C. to form the polymaleic anhydride grafting with —NH—CO— group and oligomer having carboxylic acid group at side chains, as shown in step S12; adding a silane coupling agent, as shown in step S14; carrying out a chemical ring-closure of the polyamic acid by adding a catalyst into a solution obtained from step S14, as shown in step S16; forming an organic-inorganic hybrid material solution of polymaleic anhydride-polyimide-silica by adding an alkoxysilane monomer having formula of Si(R3)4, where R3 may be the same or not the same and represents halogens, C1-6 alkoxy group, C2-6 enyloxy group and aryloxy group into a solution obtained from step S16, as shown in step S18; and forming an organic-inorganic hybrid material film of polymaleic anhydride-polyimide-silica by coating and curing the organic-inorganic hybrid material solution of polymaleic anhydride-polyimide-silica on a substrate, as shown in step S20.

Dianhydrides suitable for use in step S10 of the methods of the invention include, but are not limited to: maleic anhydride, substituted maleic anhydride, tetrahydrophthalic anhydride, substituted tetrahydrophthalic anhydride, endomethylene tetrahydrophthalic anhydride, substituted endomethylene tetrahydrophthalic anhydride; aromatic dianhydrides, for example, pyromellitic dianhydride (PMDA), 4,4′-biphthalic dianhydride (BPDA), 4,4′-(hexafluoroisopropylidene)diphthalic anhydride (6FDA), 1-(trifluoromethyl)-2,3,5,6-phenyltetracarboxylic dianhydride (P3FDA), 1,4-bis(trifluoromethyl)-2,3,5,6-phenyltetracarboxylic dianhydride (P6GDA), 1-(3′,4′-dicarboxyphenyl)-1,3,3-trimethylindane-5,6-dicarboxylic dianhydride, 1-(3′,4′-dicarboxyphenyl)-1,3,3-trimethylindane-6,7-dicarboxylic dianhydride, 1-(3′,4′-dicarboxyphenyl)-3-methylindane-5,6-dicarboxylic dianhydride, 1-(3′,4′-dicarboxyphenyl)-3-methylindane-6,7-dicarboxylic dianhydride, 2,3,9,10-perylene-tetracarboxylic dianhydride, 1,4,5,8-naphthalene-tetracarboxylic dianhydride, 2,6-dichloronaphthalene-1,4,5,8-tetracarboxylic dianhydride, 2,7-dicholronaphthalene-1,4,5,8-tetracarboxylic dianhydride, 2,3,6,7-tetrachloronaphthalene-2,4,5,8-tetracarboxylic dianhydride, phenanthryl-1,8,9,10-tetracarboxylic dianhydride, 3,3′,4,4′-diphenylketone-tetracarboxylic dianhydride, 1,2′,3,3′-diphenylketone-tetracarboxylic dianhydride, 3,3′,4,4′-biphenyl-tetracarboxylic dianhydride, 3,3′,4,4′-diphenylketone-tetracarboxylic dianhydride, 2,2′,3,3′-biphenyl-tetracarboxylic dianhydride, 4,4′-(isopropylidene)diphthalic anhydride, 3,3′-(isopropylidene)diphthalic anhydride, 4,4′-oxy-diphthalic anhydride, 4,4′-sulfanyl-diphthalic anhydride, 3,3′-oxy-diphthalic anhydride, 4,4′-(methylene)diphthalic anhydride, 4,4′-(sulfur)diphthalic anhydride, 4,4′-(ethylene)diphthalic anhydride, 2,3,6,7-naphthalene-tetracarboxylic dianhydride, 1,2,4,5-naphthalene-tetracarboxylic dianhydride, 1,2,5,6-naphthalene-tetracarboxylic dianhydride, phenyl-1,2,3,4-tetracarboxylic dianhydride, pyrazine-2,3,5,6-tetracarboxylic dianhydride, in which anhydrides preferable for use include pyromellitic dianhydride, 4,4′-biphthalic dianhydride, 4,4′-(hexafluoroisopropylidene)diphthalic anhydride (6FDA), 1-(trifluoromethyl)-2,3,5,6-phenyltetracarboxylic dianhydride (P3FDA) and 1,4-bis(trifluoromethyl)-2,3,5,6-phenyltetracarboxylic dianhydride (P6GDA).

Diamines suitable for use in step S10 of the methods of the invention include, but are not limited to: 4,4′-oxydianiline (ODA), 5-amino-1-(4′-aminophenyl)-1,3,3-trimethylindane, 6-amino-1-(4′-aminophenyl)-1,3,3-trimethylindane, 4,4′-methylene-bis(o-chloroaniline), 3,3′-dichlorodianiline, 3,3′-sulfanyldianiline, 4,4′-diaminobenzophenone, 1,5-diaminonaphthalene, bis(4-aminophenyl) diethyl silane, bis(4-aminophenyl)diphenyl silane, bis(4-aminophenyl)ethyl-phosphine oxide, N-(bis(4-aminophenyl))-N-methylamine, N-(bis(4-aminophenyl))-N-phenylamine, 4,4′-methylene-bis(2-methylaniline), 4,4′-methylene-bis(2-methoxylaniline), 5,5′-methylene-bis(2-amino-phenol), 4,4′-methylene-bis(2-methylaniline), 4,4′-oxy-bis(2-methoxylaniline), 4,4′-oxy-bis(2-chloroaniline), 2,2′-bis(4-amino-phenol), 5,5′-oxy-bis(2-amino-phenol), 4,4′-sulfur-bis(2-methylaniline), 4,4′-sulfur-bis(2-methoxylaniline), 4,4′-sulfur-bis(2-chloroaniline), 4,4′-sulfanyl-bis(2-methylalanine), 4,4′-sulfanyl-bis(2-ethoxylalinine), 4,4′-sulfanyl-bis(2-chloroalinine), 5,5′-sulfanyl-bis(2-amino-phenol), 3,3′-dimethyl-4,4′-diaminobenzophenone, 3,3′-dimethoxyl-4,4′-diaminobenzophenone, 3,3′-dichloro-4,4′-diaminobenzophenone, 4,4′-diaminobiphenyl, m-phenylenediamine, p-phenylenediamine, 4,4′-methylene-dialanine, 4,4′-sulfur-dialanine, 4,4′-sulfanyl-dialanine, 4,4′-isopropylene-dialinine, 3,3′-dimethyldialinine, 3,3′-dimethoxyldialinine, 3,3′-dicarboxydialinine, 2,4-methylphenyldiamine, 2,5-methylphenyldiamine, 2,6-methylphenyldiamine, m-dimethylphenyldiamine, 2,4-diamino-5-chlorotoluene, 2,4-diamine-6-chlorotoluene, etc., in which 4,4′-oxydianiline (ODA) is preferable.

The solvents preferable used in step S10 independently are, for example, N-methyl pyrrolidin ketone, N,N-dimethyl-formylamide, N,N-dimethyl-acetamide and diethylene glycol monomethyl ether. The solvents preferable used in step S10 in mixture of two kinds are, for example, N-methyl pyrrolidin ketone and diethylene glycol monomethyl ether, N-methyl pyrrolidin ketone and methanol, N-methyl pyrrolidin ketone and 2-methoxyethanol.

A polymaleic anhydride used in step S12 is a polymer with maleic anhydride groups at position of a main chain. The silane coupling agent used in step S14 may be an amine group coupling agent having formula of H2N—R1-Si(R2)3, where R1 represents C1-6 alkylene group such as methylene, ethylene, propylene, butylene, pentylidene and hexamethylene or arylene group such as phenylene and naphthylene; and R2 may be the same or not the same and represents C1-6 alkoxy group. Polyamic acid grafted with amine group coupling agents can be obtained by reacting amine groups of H2N—R1-Si(R2)3 with anhydride groups of polymaleic anhydride that is produced by step S 12, in which the moles of amine group coupling agents less than the diamine thereof. The amine group coupling agent having formula of H2N—R1-Si(R2)3 is a coupling agent selected from the group consisting of 3-amine-methyl trimethoxysilane (APrTMOS), 3-amine-propyl triethoxysilane (APrTEOS), 3-amine-phenyl trimethoxysilane (APTMOS) and 3-amine-phenyl triethoxysilane (APTEOS). Alternatively, the silane coupling agent for use in step S14 may be an isocyanic acid group coupling agent having formula of OCN—R1-Si(R2)3, where R1 represents C1-6 alkylene group such as methylene, ethylene, propylene, butylene, pentylidene and hexamethylene or arylene group such as phenylene and naphthylene; and R2 may be the same or not the same and represents C1-6 alkoxy group. Polyamic acid grafted with isocyanic acid group coupling agents at a position of a side chain of the polymaleic anhydride can be obtained by reacting isocyanic acid group groups of OCN—R1-Si(R2)3 with hydroxyl groups of diamine at a position of a side chain of the polymaleic anhydride that is produced by step S12.

Catalysts suitable used in step S16 may be pyridine or beta-picoline. Other tertiary amine catalysts that have a similar activity to pyridine and beta-picoline can also be used in the method. These tertiary amines include alpha picoline, 3,4-lutidine, 3,5-lutidine, 4-picoline, 4-isopropylpyridine, N,N-dimethylbenzyl amine, isoquinoline, 4-benzylpyridine, N,N-dimethyldodecylamine, triethyl amine and the like. In addition, dehydrating agents may be added in step S16. The suitable dehydrating agents include: (i) aliphatic anhydrides such as acetic anhydride, propionic anhydride, butyric anhydride, valeric anhydride and their mixtures; (ii) anhydrides of aromatic monocarboxylic acid; (iii) the mixture of aliphatic anhydrides and aromatic anhydrides; (iv) carbodimides; and (v) aliphatic ketenes. Typically, the acetic anhydride is used in excess of moles to amide acid functional groups of the polyamic acid and the acetic anhydride is used in the range of 1.2-2.4 moles based on per equivalent of polyamic acid. In one embodiment, the tertiary amine catalyst is used in the same amount of moles of the acetic anhydride.

The alkoxysilane monomer having formula of Si(R3)4 used in step S18 may be selected from the group consisting of tetramethoxy silane, tetraethoxy silane and tetrapropoxy silane. In addition, a coupling agent monomer having formula of R4Si(R5)3, where R4 is a functional group with epoxy group at end and R5 may be the same or not the same and represents halogens, C1-6 alkoxy group, C2-6 enyloxy group and aryloxy group can be added into a solution that is produced by step S18 to carry out a hydrolytic condensation reaction, and produce covalent bond combining to silica phase. The coupling agent monomer having formula of R4Si(R5)3 may be selected from the group consisting of γ-glycidoxy propyl trimethoxy silane (GTMOS) and γ-glycidoxy propyl triethoxy silane (GTEOS).

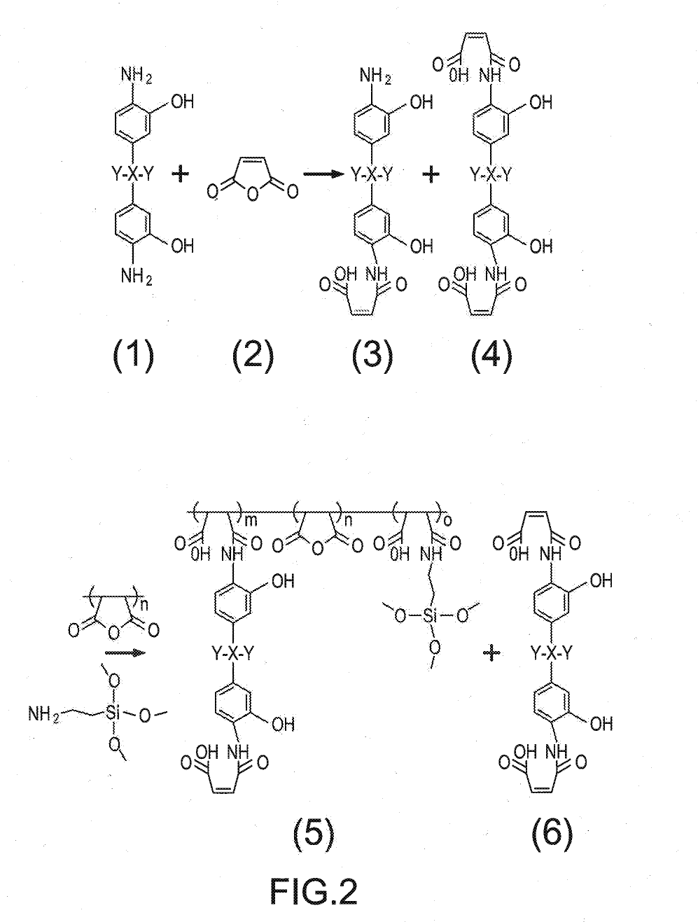

Next, please refer to FIG. 2. FIG. 2 is a diagram showing reactions for manufacturing an organic-inorganic hybrid material of polymaleic anhydride-polyimide-silica of an embodiment of the present invention, wherein a silane coupling agent for use in the reaction is an amine group coupling agent having formula of H2N—R1-Si(R2)3. In an embodiment, at first aromatic diamine (shown as structural formula (1), where X is members selected from the group consisting of C, O and benzene ring; and Y is H or CF3) reacts with maleic anhydride monomers (shown as structural formula (2)) to form polyamic acid (shown as structural formulas (3) and (4)). Next, polymaleic anhydride is added to react with the polyamic acid (shown as structural formulas (3)) produced by the previous step under a temperature below 80° C. to form the polymaleic anhydride grafting with —NH—CO— group and oligomer having carboxylic acid group at side chains, followed by the addition of an amine group coupling agent having formula of H2N—R1-Si(R2)3, where R1 represents C1-6 alkylene group such as methylene, ethylene, propylene, butylene, pentylidene and hexamethylene or arylene group such as phenylene and naphthylene; and R2 may be the same or not the same and represents C1-6 alkoxy group to obtain polyamic acid grafted with amine group coupling agents (shown as structural formula (5)) by reacting amine groups of H2N—R1-Si(R2)3 with anhydride groups of polymaleic anhydride. Also, polyamic acid shown as structural formula (6) is obtained.

Next, a chemical ring-closure of the polyamic acid grafting with —NH—CO— group and oligomer having carboxylic acid group at side chains is carried out by adding a catalyst to form a polyimide grafting with an amine group coupling agent (shown as structural formula (7)) and a polyimide shown as structural formula (8) is obtained. Next, tetraethoxy silane (TEOS) was added in presence of water and acidic catalyst or basic catalyst under a temperature range of 15° C. to 100° C. to form an organic-inorganic hybrid material solution of polymaleic anhydride-polyimide-silica (shown as structural formula (9)) with combining polyimide moiety and silica via covalent bond by a hydrolytic condensation reaction of Si—OHof TEOS and the amine group coupling agent. Also, a polyimide shown as structural formula (10) is obtained. When the polyamic acid ring closes to form a polyimide, the thermal crosslinking functional groups at the side chain positions may also close. Therefore, the thermal ring-closure step by directly heating to about 300° C. is not suitable. In the embodiment, a chemical ring-closure step is employed by using catalyst and dehydrating agent reacting with the polyamic acid at 100° C. for 4 hours to form a polyimide grafting with an amine group coupling agent (shown as structural formula (7)) and a polyimide shown as structural formula (8).

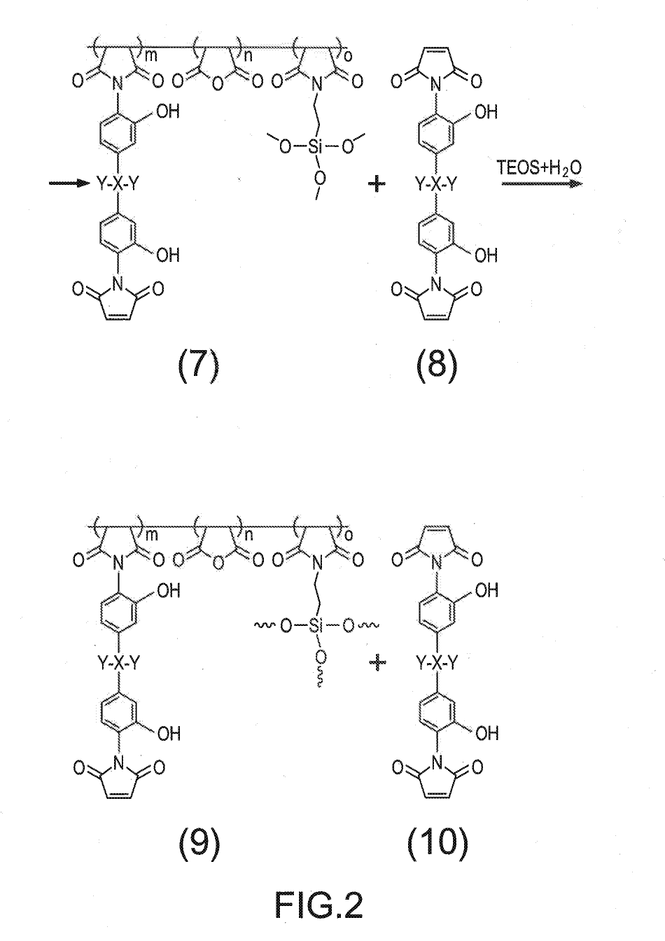

Next, please refer to FIG. 3. FIG. 3 is a diagram showing reactions for manufacturing an organic-inorganic hybrid material of polymaleic anhydride-polyimide-silica of another embodiment of the present invention, wherein a silane coupling agent for use in the reaction is an isocyanic acid group coupling agent having formula of OCN—R1-Si(R2)3. In an embodiment, at first aromatic diamine (shown as structural formula (11), where X is members selected from the group consisting of C, O and benzene ring; and Y is H or CF3) reacts with maleic anhydride monomers (shown as structural formula (12)) to form polyamic acid (shown as structural formulas (13) and (14)). Next, polymaleic anhydride is added to react with the polyamic acid (shown as structural formulas (13)) produced by the previous step under a temperature below 80° C. to form the polymaleic anhydride grafting with —NH—CO— group and oligomer having carboxylic acid group at side chains, followed by the addition of an amine group coupling agent having formula of OCN—R1-Si(R2)3, where R1 represents C1-6 alkylene group such as methylene, ethylene, propylene, butylene, pentylidene and hexamethylene or arylene group such as phenylene and naphthylene; and R2 may be the same or not the same and represents C1-6 alkoxy group to obtain polyamic acid grafted with isocyanic acid group coupling agents (shown as structural formula (15)) by reacting isocyanic acid groups of OCN—R1-Si(R2)3 with hydroxyl groups of aromatic diamine at side chains of polymaleic anhydride. Also, polyamic acid shown as structural formula (16) is obtained.

Next, a chemical ring-closure of the polyamic acid grafting with —NH—CO— group and oligomer having carboxylic acid group at side chains is carried out by adding a catalyst to form a polyimide grafting with an isocyanic acid group coupling agent (shown as structural formula (17)) and a polyimide shown as structural formula (18) is obtained. Next, tetraethoxy silane (TEOS) was added in presence of water and acidic catalyst or basic catalyst under a temperature range of 15° C. to 100° C. to form an organic-inorganic hybrid material solution of polymaleic anhydride-polyimide-silica (shown as structural formula (19)) with combining polyimide moiety and silica via covalent bond by a hydrolytic condensation reaction of Si—OH of TEOS and the isocyanic acid group coupling agent. Also, a polyimide shown as structural formula (20) is obtained. When the polyamic acid ring closes to form a polyimide, the thermal crosslinking functional groups at the side chain positions may also close. Therefore, the thermal ring-closure step by directly heating to about 300° C. is not suitable. In the embodiment, a chemical ring-closure step is employed by using catalyst and dehydrating agent reacting with the polyamic acid at 100° C. for 4 hours to form a polyimide grafting with an isocyanic acid group coupling agent (shown as structural formula (17)) and a polyimide shown as structural formula (18).

### Example

To a 1 L 3-neck flask equipped with a mechanical stirring device, reflux condenser introducing nitrogen gas was added 1.602 g (8 mmol) 4,4′-oxydianiline (ODA), which was dissolved by stirring vigorously in 200 g solvent of dimethyl-acetamide for 10 minutes, followed by the slow addition of 4.443 g (10 mmol) 4,4′-(hexafluoroisopropylidene)diphthalic anhydride (6FDA), while maintaining the solution at room temperature for 24 hours to obtain a polyamic acid solution. To the polyamic acid solution was added 20 mmol acetic anhydride and 20 mmol pyridine, and heated to 100° C. for 4 hours to complete chemical ring-closure of the maleamic acid. After the temperature of resultant solution was reduced to room temperature, 886 mg (4 mmol) 3-(triethoxysilyl) propyl isocyanate was added, and stirred to react at room temperature for 4 hours resulting in combining with polyimide. This was followed by the addition of 1.250 g of tetramethoxy silane (TMOS) and stirred for 30 minutes, followed by the addition of 30 mg de-ionized water to react for 24 hours at room temperature resulting in the desired organic-inorganic hybrid material solution of polymaleic anhydride-polyimide-silica.

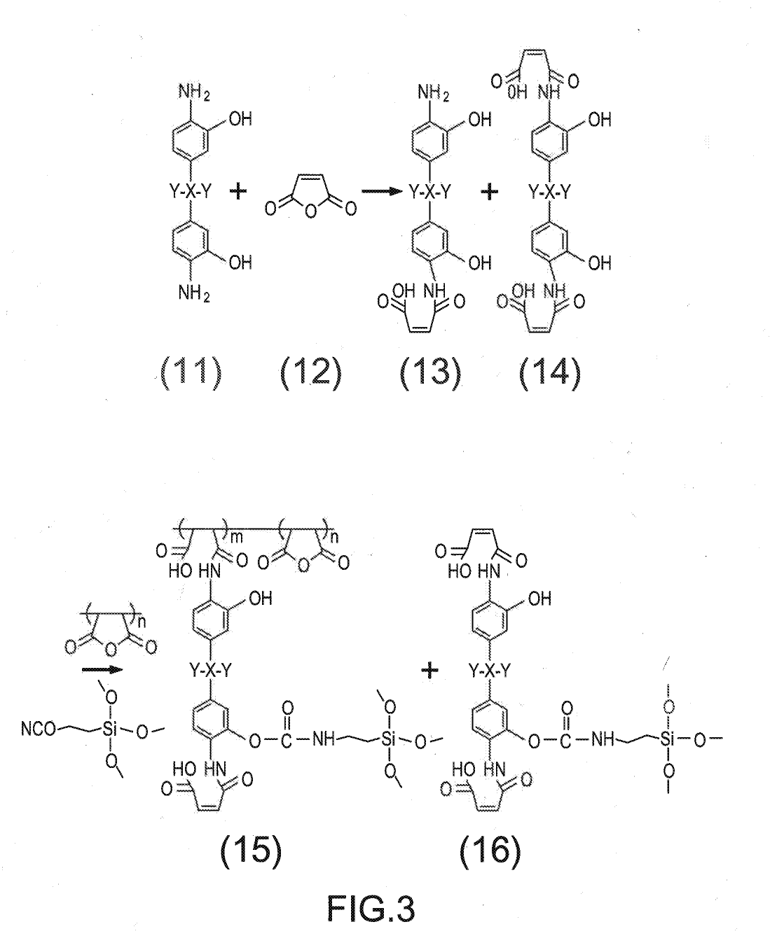

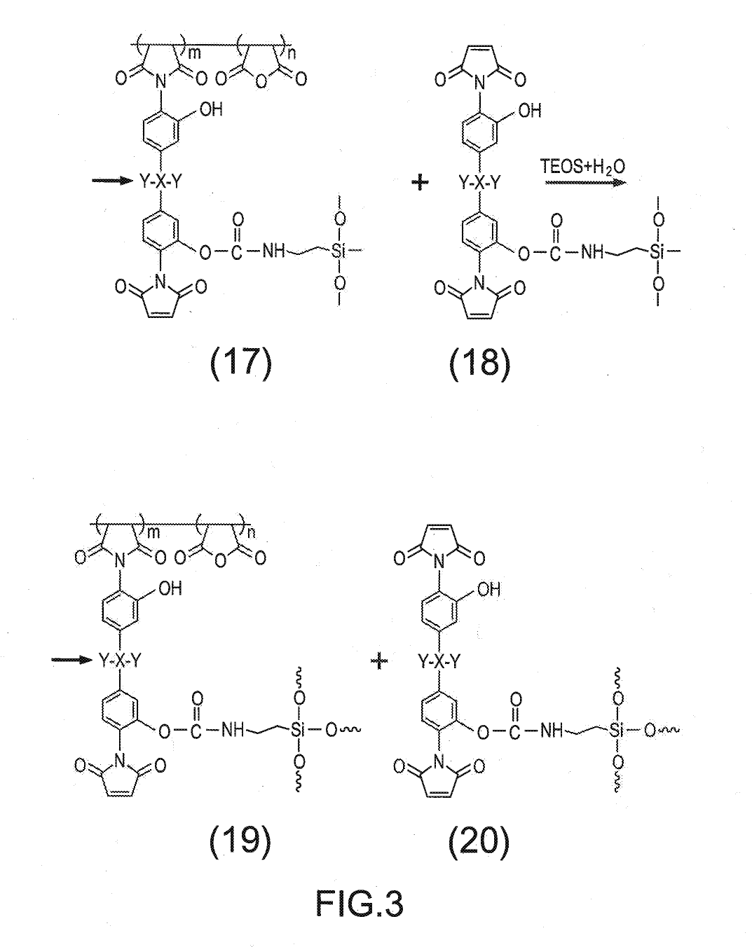

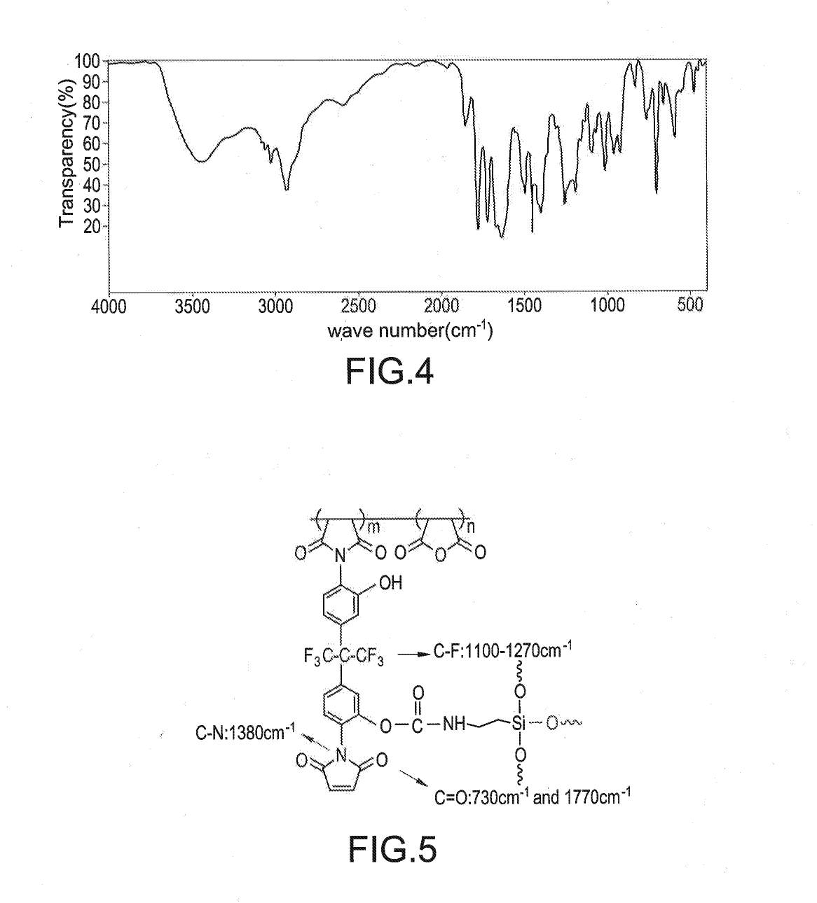

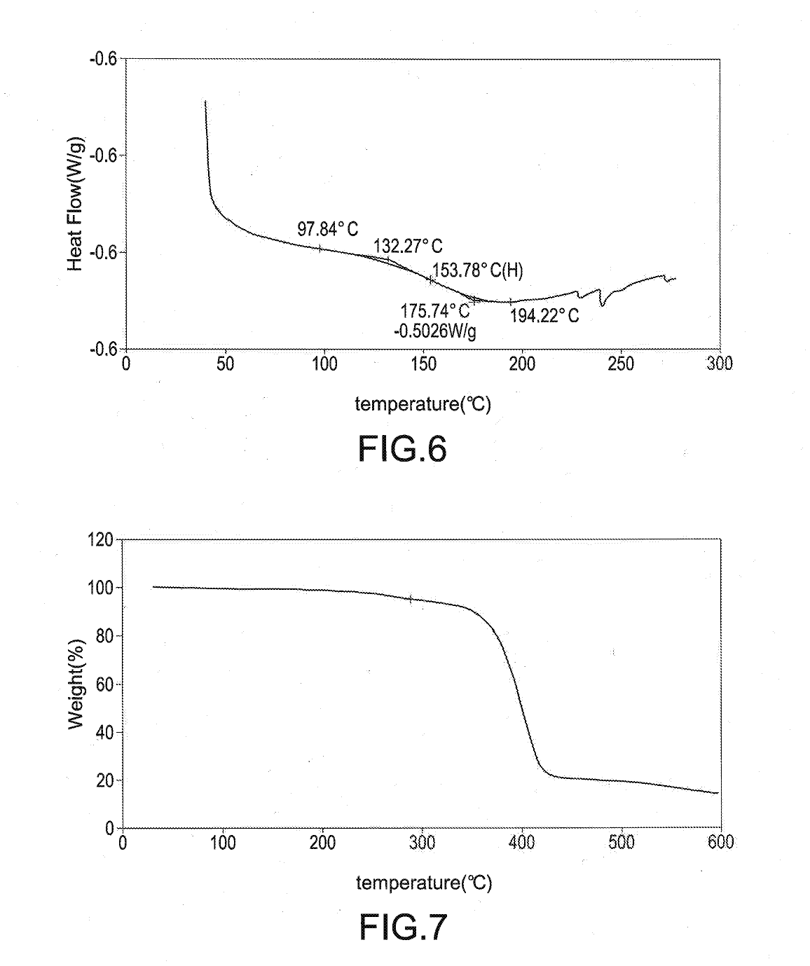

The characteristic tests of the product were carried out, and the results were shown in FIGS. 4-7. FIG. 4 is a graph showing IR absorption spectroscopy of an organic-inorganic hybrid material of polymaleic anhydride-polyimide-silica of an embodiment of the invention. FIG. 5 is an analytical result of FIG. 4. As can be seen in FIG. 4, wave numbers 1538 cm-1 and 1650 cm-1 represent respectively N—H bending peak and C═O stretching peak of polyamic acid structure. The above two peaks may disappear and new peaks may form after ring closure of the polyamic acid and formation of polyimide. The new peaks include wave number 1380 cm-1 representing tertiary amine of polyimide structure, wave numbers 730 cm-1 and 1770 cm-1 representing C═O stretching peak of polyimide structure, as shown in FIG. 5. FIG. 6 is a graph showing phase transition of an organic-inorganic hybrid material of polymaleic anhydride-polyimide-silica of the invention measured by differential scanning calorimetry (DSC). As can be seen in FIG. 6, glass transition temperature of the product is about 150° C. FIG. 7 is a graph showing the weight residue of an organic-inorganic hybrid material of polymaleic anhydride-polyimide-silica of the invention when heated to various temperatures. As can be seen in FIG. 7, 5 wt % thermal gravimetric temperature of the product is about 288° C.

Further, the invention provides a prepreg formed of a fiberglass cloth impregnated in the above organic-inorganic hybrid material solution of polymaleic anhydride-polyimide-silica. The prepreg has excellent temperature resistance and mechanical strength, and can be an insulation layer material for use in copper foil substrates and circuit boards.

Also, the invention provides a copper foil substrate including a copper foil laminated with the above prepreg. The copper foil substrate has excellent temperature resistance and mechanical strength, and bonds with electronic elements to form an electronic device that can be operated in a strict environment of high temperature and high humidity without deterioration.

While the invention is described in by way of examples and in terms of preferred embodiments, it is to be understood that the invention is not limited thereto. On the contrary, the aim is to cover all modifications, alternatives and equivalents falling within the spirit and scope of the invention as defined by the appended claims.

What is claimed is:

1. A method for manufacturing an organic-inorganic hybrid material film of polymaleic anhydride-polyimide-silica comprising steps of:
(a) dissolving and reacting a dianhydride with a diamine in a solvent to form polyamic acid;
(b) reacting polymaleic anhydride with the polyamic acid produced by the step (a) to form the polymaleic anhydride grafting with —NH—CO— group and oligomer having carboxylic acid group at side chains;
(c) adding a silane coupling agent;
(d) carrying out a chemical ring-closure of the polyamic acid by adding a catalyst into a solution obtained from step (c);
(e) forming an organic-inorganic hybrid material solution of polymaleic anhydride-polyimide-silica by adding an alkoxysilane monomer having formula of Si(R3)4, where R3 may be the same or not the same and represents halogens, C1-6 alkoxy group, C2-6 enyloxy group and aryloxy group into a solution obtained from step (d); and
(f) forming an organic-inorganic hybrid material film of polymaleic anhydride-polyimide-silica by coating and curing the organic-inorganic hybrid material solution of polymaleic anhydride-polyimide-silica on a substrate.

2. The method for manufacturing an organic-inorganic hybrid material film of polymaleic anhydride-polyimide-silica of claim 1, wherein the silane coupling agent of step (c) is an amine group coupling agent having formula of H2N—R1-Si(R2)3, where R1 represents C1-6 alkylene group or arylene group; and R2 may be the same or not the same and represents C1-6 alkoxy group, and polyamic acid grafted with amine group coupling agents can be obtained by reacting amine groups of H2N—R1-Si(R2)3 with anhydride groups of polymaleic anhydride that is produced by step (b), in which the moles of amine group coupling agents less than the diamine thereof.

3. The method for manufacturing an organic-inorganic hybrid material film of polymaleic anhydride-polyimide-silica of claim 2, wherein the amine group coupling agent having formula of H2N—R1-Si(R2)3 is a coupling agent selected from the group consisting of 3-amine-methyl trimethoxysilane (APrTMOS), 3-amine-propyl triethoxysilane (APrTEOS), 3-amine-phenyl trimethoxysilane (APTMOS) and 3-amine-phenyl triethoxysilane (APTEOS).

4. The method for manufacturing an organic-inorganic hybrid material film of polymaleic anhydride-polyimide-silica of claim 1, wherein the silane coupling agent of step (c) is an isocyanic acid group coupling agent having formula of OCN—R1-Si(R2)3, where R1 represents C1-6 alkylene group or arylene group; and R2 may be the same or not the same and represents C1-6 alkoxy group, and polyamic acid grafted with isocyanic acid group coupling agents at a position of a side chain of the polymaleic anhydride can be obtained by reacting isocyanic acid group groups of OCN—R1-Si(R2)3 with hydroxyl groups of diamine at a position of a side chain of the polymaleic anhydride that is produced by step (b).

5. The method for manufacturing an organic-inorganic hybrid material film of polymaleic anhydride-polyimide-silica of claim 1, wherein the alkoxysilane monomer having formula of Si(R3)4 used in step (e) is a member selected from the group consisting of tetramethoxy silane, tetraethoxy silane and tetrapropoxy silane.

6. The method for manufacturing an organic-inorganic hybrid material film of polymaleic anhydride-polyimide-silica of claim 1, further a coupling agent monomer having formula of R4Si(R5)3, where R4 is a functional group with epoxy group at end and R5 may be the same or not the same and represents halogens, C1-6 alkoxy group, C2-6 enyloxy group and aryloxy group is added into a solution that is produced by step (e) to carry out a hydrolytic condensation reaction, and produce covalent bond combining to silica phase.

7. The method for manufacturing an organic-inorganic hybrid material film of polymaleic anhydride-polyimide-silica of claim 6, wherein the coupling agent monomer having formula of R4Si(R5)3 is a member selected from the group consisting of γ-glycidoxy propyl trimethoxy silane (GTMOS) and γ-glycidoxy propyl triethoxy silane (GTEOS).

8. The method for manufacturing an organic-inorganic hybrid material film of polymaleic anhydride-polyimide-silica of claim 1, wherein the solvent used in step (a) is a member selected from the group consisting of N-methyl pyrrolidin ketone, N,N-dimethyl-formylamide, N,N-dimethyl-acetamide and diethylene glycol monomethyl ether.

9. The method for manufacturing an organic-inorganic hybrid material film of polymaleic anhydride-polyimide-silica of claim 1, wherein the catalyst used in step (d) is pyridine or beta-picoline.

10. The method for manufacturing an organic-inorganic hybrid material film of polymaleic anhydride-polyimide-silica of claim 1, wherein to the step (d), a dehydrating agent is added.

11. The method for manufacturing an organic-inorganic hybrid material film of polymaleic anhydride-polyimide-silica of claim 10, wherein the dehydrating agent is acetic anhydride, propionic anhydride, butyric anhydride, valeric anhydride and their mixtures; anhydrides of aromatic monocarboxylic acid; the mixture of aliphatic anhydrides and aromatic anhydrides; carbodimides; and aliphatic ketenes.

12. An organic-inorganic hybrid material film of polymaleic anhydride-polyimide-silica manufactured by the method of claim 1, the polymaleic anhydride acting as a main chain, and the polymaleic anhydride grafting with a plurality of short chains at side chain positions, wherein each short chain has polyimide moiety and silica moiety.

13. A prepreg formed of a fiberglass cloth cladding in the organic-inorganic hybrid material film of polymaleic anhydride-polyimide-silica of claim 12.

14. A copper foil substrate including at least one copper foil laminated with the prepreg of claim 13.
